(19) United States
(12) Patent Application Publication
(10) Pub. No.: US 2022/0186088 A1
(43) Pub. Date: Jun. 16, 2022

(54) MULTICOMPONENT SYSTEM, AND METHOD FOR PRODUCING A MULTICOMPONENT SYSTEM

(71) Applicant: Sphera Technology GmbH, Munich (DE)

(72) Inventor: Janine-Melanie Potreck, Munich (DE)

(73) Assignee: Sphera Technology GmbH, Munich (DE)

(21) Appl. No.: 17/598,146

(22) PCT Filed: Mar. 24, 2020
(86) PCT No.: PCT/EP2020/058131

§ 371 Date: Sep. 24, 2021

(30) Foreign Application Priority Data
Mar. 25, 2019 (DE) DE10 2019107633.1

(51) Int. Cl. C09J 9/02; H01B 1/22; C08K 9/08; C08K 9/10; C09J 11/04

(52) U.S. Cl. CPC C09J 9/02; H01B 1/22; C08K 9/08; C08K 2201/005; C09J 11/04; C08K 2201/001; C08K 2201/011; C08K 9/10

(57) ABSTRACT

A multicomponent system contains at least one first substance and at least one second substance. The multicomponent system can be activated, and the first substance and the second substance are provided in multiple portions, where the first portions are formed with at least one first functional group and are provided with a first linker, and the second portions are formed with at least one second functional group and are provided with a second linker. The first functional group reacts with the second functional group via a specified interaction which connects the two groups together, and the distance between the functional groups and the respective portions is tuned by the respective linker.

The present invention relates to a multi-component system and a method of manufacturing a multi-component system.

Multi-component systems are already known from the prior art.

For example, multi-component systems, such as two-component systems, are used in bonding technology.

In this field, for example, special hand applicators as described in DE 202017000446 U1 are used to activate and then apply the adhesive system.

US 2012/0107601 A1 further relates to a capsule system that responds to pressure and releases fluids accordingly.

Other capsule systems are known, for example, from WO 2017/192407 A1, U.S. Pat. No. 8,747,999 B2, WO 2017 042709 A1, WO 2016/049308 A1 and WO 2018/028058 A1.

Capsule-in-capsule systems are further known from, for example, U.S. Pat. No. 9,637,611 B2, WO 2002/060573 A2 or U.S. Pat. No. 4,891,172 A.

Capsule systems have been passive systems throughout until now. This means that they have one or more capsules and the component of interest is enclosed in the capsule(s). At a defined point in time, also known as activation, the contents of the capsule are emptied and the component is released accordingly.

However, it would be desirable to be able to better control the release of the components and their mixing.

It is the object of the present invention to further form a multi-component system as well as a method for manufacturing a multi-component system of the type mentioned hereinabove in an advantageous manner, particularly in that the dosing of individual components of multi-component systems and the mixing thereof can be better controlled, in order to thus improve the efficiency of the reaction of the multi-component system.

This object is solved according to the invention by a multi-component system having the features of claim 1. According to this, a multi-component system of at least one first substance and at least one second substance is provided, wherein the multi-component system can be activated, wherein the first substance and the second substance are present in several portions of substance, wherein the first portions of substance are formed with at least one first functional group and are provided with a first linker, and wherein the second portions of substance are formed with at least one second functional group and are provided with a second linker, wherein the first functional group reacts with the second functional group via a predefined interaction via weak or strong interaction, but preferably via covalent bonding, and links them to one another, and wherein the distance of the functional groups to the respective portion of substance is tuned by the respective linker.

The invention is based on the basic idea that at least one first substance and at least one second substance are arranged in a defined manner relative to one another in a defined spatial arrangement with the aid of linkers and their connection by the functional groups. Thus, it is now possible to arrange the first substance and the second substance separately from each other in a defined ratio and defined distance correspondingly. By appropriate activation, the substances are then mixed with each other and the reaction of the substances with each other is enabled.

In principle, it is also conceivable that the first and second substances are identical, so that a one-component system is present per se. Such systems are also to be understood as multi-component systems in the above sense.

Furthermore, it may be provided that the first linker is longer than the second linker or vice versa. This results in the advantage that, for example, the first substances take a greater distance from each other than the first substance takes from the second substance after appropriate linking. This results in the second substance always being spatially arranged between the first substances, which favors mixing. This also favors an adjustment of the concentration and/or volume ratios of the substances relative to each other.

A linker can be any form of connection between a capsule and a functional group.

A linker can also be any type of direct link between a capsule and a functional group.

Furthermore, it is conceivable that the first portions of substance and the second portions of substance differ in that the first portions of substance are connected or connectable to a greater number of portions of substance than the second portions of substance or vice versa. This allows the concentration and/or volume ratio and the relative ratio of the substances to each other to be adjusted.

The functional groups may be homogeneous or heterogeneous. It is conceivable, for example, that a substance and the associated functional groups are heterogeneous, i.e. that different functional groups can be used. This is desirable, for example, if it is desired to achieve that, for example, certain linkers are first provided with protective groups during manufacturing and are to be used to form certain bonds, for example first substance to first substance or second substance to second substance or also first substance to second substance. It is also conceivable that a first functional group enables two capsules to be linked, and a second, different functional group enables capsules to be bound to surfaces or fibres. It is also conceivable that a first functional group enables binding of two capsules, and a second, different functional group enables properties of the capsules to be altered, e.g. biocompatibility, solubility, or similar properties. It is also conceivable that heterogeneous functional groups enable a three- or multi-component system to be formed.

However, it is also conceivable that all functional groups are formed homogeneously, i.e. identically. In the case of heterogeneous formation, it is also conceivable that this is combined with further properties or differences in the design of the linkers (e.g. length, angle, type of linker, etc.).

The first portions of substance may have a substantially identical size and/or the second portions of substance may have a substantially identical size. Size may mean in particular the spatial extent, but also the mass or the volume occupied. Conceivably, the first portions of substance and the second portions of substance each have an identical size or quantity.

In particular, however, it is also conceivable that the first portions of substance and the second portions of substance have a different size.

The choice of size also determines the respective (local) volume and/or the respective local concentration of the respective substance.

The multi-component system can have a network structure with interstices, the network structure being formed by portions of the first substance, an environmental medium and, at least in sections, at least one portion of the second substance being arranged in each of the interstices. The result is an improved mixing of the individual substances and thus also an improved material consumption.

Furthermore, it may be provided that a portion of substance of the first substance and/or the second substance is arranged in a capsule, in particular a nanocapsule and/or microcapsule. The encapsulation makes it easily possible to be able to provide a defined mass or volume of the first and/or second substance for the multi-component system. In the case of a multi-component capsule system or, for example, a two-component capsule system (2C capsule system), it is possible for the capsule contents to be bound to one another in a defined number and/or a defined ratio and spacing in separate spaces until the capsules are activated and thus their contents can react with one another or are forced to react with one another or mix if the capsules have the same contents. One portion of substance of a substance is arranged or packaged per capsule. It would also be conceivable that a capsule contains several portions of substance. An arrangement of capsules having both first substances and second substances can also be referred to as a capsule complex and has approximately a function comparable to a (mini) reaction flask, in which the reagents are mixed with each other after activation at a defined time and the reaction of the substances with each other is initiated. Due to the large number of these capsule complexes, the mode of action is added up and there is a greater effect or the mixing and reaction of the substances is improved. Further advantages result from the better mixing of the individual substances or reaction components with each other and thus—compared to previous systems—a higher turnover can be achieved with a simultaneously lower material input. In the case of a one-component system, mixing can be significantly improved. Particularly in the case of highly viscous adhesive tapes, complete cross-linking through the adhesive tape can thus be achieved with a one-component adhesive.

In particular, it may be provided that a capsule of the first substance has a different size than a capsule of the second substance, in particular wherein the capsule of the first substance is larger than the capsule of the second substance. This provides an adjustment of the ratio of the volumes of the first substance in relation to the second substance (or vice versa), and also an adjustment of the activation behavior.

It is further conceivable that the capsules of the first substance have an identical size. This also enables to adjust the activation behavior.

Conceivably, the activation of the capsules of the multi-component system is effected by at least one of a change in pressure, pH, UV radiation, osmosis, temperature, light intensity, humidity, or the like.

It is conceivable to use one or more activation mechanisms in parallel.

Possible capsule types include, for example, dual-capsules, multi-core capsules, capsules with cationic or anionic character, capsules with different shell materials, capsules with multiple shells, capsules with multiple layers of shell material (so-called multilayer microcapsules), capsules with metal nanoparticles, matrix capsules and/or hollow capsules, capsules with a dense shell material, e.g. an absolutely dense shell material, porous capsules and/or empty porous capsules (for example to encapsulate odors).

The first substance and the second substance may be components of a multi-component adhesive, in particular a two-component adhesive.

In principle, other fields of application are also possible.

In particular, it may be provided that the first substance and the second substance are components of a one-component adhesive. In other words, the first substance and the second substance may be the same substance.

The capsules are formed or functionalized with linkers and with functional groups. The linkers are intended to crosslink the capsules with one another. It may be provided that the functional groups are further provided with a protecting group. The distance between the capsules may be tuned by the length of the linkers. The length of the linkers should be chosen such that the radius of the contents of the released liquid of the capsules slightly overlaps with the contents of the adjacent capsules to ensure crosslinking. For a higher viscosity environmental medium (such as an adhesive tape), the length of the linkers would be smaller than for a lower viscosity medium such as a paste or liquid.

In general, intra-crosslinking of capsules is possible. Here, capsules of the same capsule population are cross-linked with each other.

In general, it is possible to crosslink capsules with the same content via intra-crosslinking.

In general, inter-crosslinking of capsules is possible as an alternative or in addition. Here, capsules from at least two different capsule populations are cross-linked.

In general, it is possible that capsules with different contents are networked via inter-crosslinking.

It is conceivable that in the case of chemically curing adhesives, resin and hardener are present in the two-component system with two separate reaction chambers in a defined volume ratio in separate capsules and are protected against the activation reactions under storage conditions. The curing reaction is then triggered by, for example, changes in pressure, pH, UV radiation, osmosis, temperature, light intensity, humidity or the exclusion of air.

The capsules of a one-component capsule system or multi-component capsule system, e.g. a two-component capsule system, can be introduced into the gas phase, into pasty medium, into viscous medium, into highly viscous medium, into liquid systems and/or placed on solid surfaces.

It is conceivable, for example, that the capsules are contained in a spray (spray adhesive).

It is conceivable that a multi-component system, for example a two-component adhesive, is incorporated in a pasty medium as an environmental medium. This may enable the adhesive to be applied very precisely to a space to be bonded, for example a surface. The two-component adhesive would not yet be activated until activation, and the process time as well as the activation can be tuned individually.

It is conceivable that the capsules are attached to a surface, for example a carrier material. For example, the capsules may be contained in and/or on a double-sided or single-sided carrier material. The carrier material may comprise, for example, a plastic, a plastic film or a metal or a metal foil or a plastic foam or a textile fabric or a paper. It is also possible that the carrier material is further processed, for example by printing or die cutting, or otherwise.

One possible application of a double- or single-sided carrier material comprising the capsules of a one-component capsule system or multi-component capsule system, e.g. a two-component capsule system, is an adhesive tape and/or adhesive strip and/or adhesive label.

One possible application of a double- or single-sided carrier material comprising the capsules of a one-component capsule system or multi-component capsule system, e.g. a two-component capsule system, is an adhesive tape and/or adhesive strip and/or adhesive label for covering wounds in humans or animals. An application to plants, e.g. trees, is also generally possible. For example, the carrier material may be applied to the skin and/or body surface of the human or animal or plant. It is also possible that the carrier material is applied inside the (body) of the human or animal or plant.

In particular, this can be used to cover wounds in humans, animals or plants. It is possible to selectively agglutinate wounds. Thereby, it is provided that a pressure-sensitive adhesive on a double-sided or single-sided carrier material enables an initial adhesion to place the carrier material. Cross-linking takes place via activation of the capsules, which results in final adhesion. Alternatively or additionally, the restoration of a tissue, e.g. bone and/or cartilage tissue, nerve tissue, muscle tissue, fatty tissue, epithelial tissue, enamel, dentin, pulp, parenchyma, kellenchyma, sclerencym, epidermis, periderm, xylem, phloem or organ, which has been destroyed, for example, by accident, injury, surgery or other causes, can thus be achieved by placing a double-sided or single-sided carrier material of single- or multi-component adhesives.

Conceivably, a surface to be bonded is formed or provided with (i.e., functionalized with) a functional group complementary to a functional group with which two-component microcapsules have been functionalized. The two-component microcapsules can be bound to the surface to be bonded. Thus, the surface to be bonded may be formed in a non-tacky manner. The time, as well as the type of activation of the two-component microcapsules can be precisely tuned. This can find application, for example, in bonding in the micro range, such as bonding electronics, displays or the like. It is also conceivable that it may find application in the area of deep soft tissue injuries in humans or animals. It is conceivable that deep and/or larger wounds can also be bonded by the described method. It is conceivable that deep and/or large wounds can be glued in a minimally invasive manner. In general, bonding of human, animal or plant tissues and/or organs of any kind is conceivable.

In particular, it is conceivable that the capsules of a one-component capsule system or multi-component capsule system, e.g. a two-component capsule system additionally or alternatively contain pharmacologically active substances, for example drugs including antibiotics, growth factors, disinfectants, or the like. This may, for example, enable better wound healing or adhesion of tissues or organs of any kind.

It is also conceivable that the capsules of a one-component capsule system or multi-component capsule system, e.g. a two-component capsule system, are porous capsules. Porous capsules may be used to absorb liquids and/or odors. For example, porous capsules may conceivably be used to absorb wound fluids in wounds of animals, humans, or even plants.

It is also possible that a selected release profile is achieved via the capsules of a multi-component capsule system, for example a two-component capsule system. For example, a gradual and/or delayed release of drugs or growth factors and/or active substances of all kinds is conceivable.

It is conceivable that in a two-component capsule system for faster healing of a wound, a first capsule population with fibrin is activated immediately, but a second capsule population with antibiotics has a prolonged activation mechanism so that antibiotic release is delayed compared to fibrin release. Additionally, it would be possible to insert an empty, porous capsule that absorbs odors and/or wound fluid.

Conceivably, a two-component microcapsule system includes a first capsule population comprising an aqueous component (first phase) and a second capsule population comprising an oily component (second phase). Conceivably, a two-component microcapsule system thus enables the aqueous component and the oil-containing component, i.e. the first phase and the second phase, to be brought into solution in a defined ratio. Conceivably, a two-phase product based on a two-component microcapsule system with a defined ratio (of first phase to second phase) can thus be obtained. For example, it is conceivable that a two-phase product based on a two-component microcapsule system can be applied to a tissue/fiber in a defined ratio. Conceivably, a two-phase product based on a two-component microcapsule system prevents substances from drying out, and enables substances to be stored in a common packaging. In general, such a system can be used to ensure that reactions take place more effectively than with conventional systems.

It is also conceivable that two capsule populations of a two-component capsule system are bound together on a carrier material in a batch process with the same content but with different activation mechanisms by intra-crosslinking. This may allow a longer lasting release of e.g. pharmacologically active substances compared to a one-component capsule system.

It is also conceivable that in a two-component capsule system, unstable substances are stored for a longer period of time in their more stable form in the ambient medium by encapsulation. Only when the capsules are activated, the stable component in the first capsule is reacted with an activator from the second capsule and converted into the reactive form.

Another possible application of a double-sided or single-sided carrier material containing the capsules is an adhesive tape and/or adhesive strips in the field of personal hygiene, in the manufacture or repair of clothing and/or shoes, in the building or handicraft sector, in DIY, carpentry, in the automotive industry, adhesive technology, the electrical industry or the like.

It is also conceivable that the capsules of the one-component capsule system and/or the two-component capsule system are applied in the field of care products for humans, animals, plants or objects.

It is conceivable that a multi-component system, for example a two-component system, can also be used for self-healing products.

It is possible for a monomer to be encapsulated in a first capsule and an activator to be encapsulated in another capsule. Through targeted activation, a capsule complex can react with the surrounding medium.

It is conceivable, for example, that capsules of a two-component system are introduced into paper. Sugar monomers may be encapsulated in the first capsule population, and a corresponding activating enzyme may be encapsulated in the second capsule population. Activation may cause the capsules to burst, and the activating enzyme may bind the sugar monomers to the fibers of the paper. It is conceivable that one or more fractures can be repaired in this way. Conceivably, this principle could be applied to fibers of any type, for example plastic fibers.

Generally, monomers may be present in a first capsule population, and an initiator for polymerization of the monomers in the first capsule population may be present in another capsule population.

This principle can be applied to monomers of all types.

In general, two monomers may also be present in different capsules.

For example, the carboxylic acid may be present in a first capsule and the diol may be present in a second capsule. By activating the capsules, the polycondensation can be activated and the two monomers react to form a polyester.

In general, a three-capsule system is also conceivable. The first and second capsules may each contain an identical or different monomer. The third capsule may contain an initiator.

For example, the polycondensation of phenoplast would be possible, wherein the phenol is present in one capsule and the aldehyde is present in another capsule. The initiator is present in the third capsule.

In general, this principle can be applied to any polymerization.

It is possible that the capsules contain, at least in part, one or more fragrances, colorants, fillers, skin care products, growth factors, hormones, vitamins, trace elements, fats, acids, bases, bleaching agents, alcohols, proteins, enzymes, nucleic acids, hydrogels or the like.

It is also conceivable that the capsules of the one-component capsule system or the two-component capsule system are applied in the field of cleaning agents. Accordingly, it is possible that the capsules at least partially contain one or more fragrances, dyes, detergents, surfactants, alcohols, acids, bases, bleaching agents, enzymes or the like.

It is also conceivable that the capsules of the one-component capsule system or the two-component capsule system are applied in the field of diagnostic methods. Accordingly, it is possible that the capsules at least partially contain contrast agents, fluorescent substances and/or dyes.

In particular, it is conceivable that homogeneously and/or heterogeneously functionalized capsule populations of a two-component capsule system are covalently bound to one another. In particular, it is conceivable that homogeneously and/or heterogeneously functionalized capsule populations of a two-component capsule system are covalently bound to one another by intra-crosslinking and/or inter-crosslinking. Both capsule populations may each be filled with different substances, for example different dyes. It is conceivable that one capsule population is emptied upon a particular event by a particular activation mechanism, and the other capsule population is emptied upon a second particular event by a particular activation mechanism. When both events occur, the two capsule contents mix to produce a particular color.

Conceivably, a carrier material having at least one functional group is also formed to enable attachment to a surface of functionalized capsules.

In particular, it is conceivable that at least a portion of a surface to be bonded is proovided with functional groups. In addition, capsules of a one-component capsule system and multi-component capsule system can be formed with functional groups as described above. Then, the capsules are covalently bound to the functionalized surface by crosslinking. By activating the capsules, adhesive is discharged and/or intermixed, thereby developing adhesive properties.

In addition, the surface of the backing material of an adhesive tape may be functionalized. The one- and multi-component systems are mixed into the pressure-sensitive adhesive. In the next step, part of the capsule complexes is bound to the surface of the backing material.

In another embodiment, the capsule complexes may be applied to the entire or portions of the surface of the pressure sensitive adhesive.

It is generally possible to produce the capsules by solvent evaporation, thermogelling, gelation, interfacial polycondensation, polymerization, spray drying, fluidized bed, droplet freezing, extrusion, supercritical fluid, coacervation, air suspension, pan coating, co-extrusion, solvent extraction, molecular incorporation, spray crystallization, phase separation, emulsion, in situ polymerization, insolubility, interfacial deposition, emulsification with a nanomole sieve, ionotropic gelation method, coacervation phase separation, matrix polymerization, interfacial crosslinking, congealing method, centrifugation extrusion, and/or one or more other methods.

It is generally possible to prepare capsules by physical methods, chemical methods, physiochemical methods, and/or the like.

It is generally possible for the shell of the capsules to comprise at least one polymer, wax resin, protein, polysaccharide, gum arabic, maltodextrin, inulin, metal, ceramic, acrylate, microgel, phase change material and/or one or more other substances.

It is generally possible that the shell of the capsules is non-porous or not entirely porous. It is generally possible that the shell of the capsules is almost completely impermeable or completely impermeable.

It is generally possible that the core of the capsules is solid, liquid, and/or gaseous. In addition, it is possible that the core of the capsules comprises at least one phase change material, enzyme, carotenoid, living cells, at least one phenolic compound, or the like.

It is generally possible for the capsules to be formed with linear polymers, polymers with multivalence, star-shaped polyethylene glycols, self-assembled monolayer (SAM), carbon nanotubes, ring-shaped polymers, dendrimers, ladder polymers, and or the like.

Possible protecting groups include acetyl, benzoyl, benzyl, ß-methoxyethoxymethyl ether, methoxytriyl, 4-methoxyphenyl)diphenylmethyl, dimethoxytrityl, bis-(4-methoxyphenyl)phenylmethyl, methoxymethyl ether, p-methoxybenzyl ether, methyl thiomethyl ether, pivaloyl, tetrahydrofuryl, tetrahydropyranyl, trityl, triphenyl methyl, silylether, tert-butyldimethylsilyl, tri-iso-propylsilyloxymethyl, triisopropylsilyl, methyl ether, ethoxyethyl ether.p-methoxybenzylcarbonyl, tert-butyloxycarbonyl, 9-fluorenylmethyloxycarbonyl, carbamates, p-methoxybenzyl, 3,4-dimethoxybenzyl, p-methoxyphenyl, one or more tosyl or nosyl groups, methyl esters, benzyl esters, tert-butyl esters, 2, 6-di-substituted phenol esters (e.g. 2,6-dimethylphenol, 2,6-diisopropylphenol, 2,6-di-tert-butylphenol), silyl esters, orthoesters, oxazoline, and/or the like.

Possible materials for coating the capsules include albumin, gelatin, collagen, agarose, chitosan, starch, carrageenan, polystarch, polydextran, lactides, glycolides and co-polymers, polyalkylcyanoacrylate, polyanhydride, polyethyl methacrylate, acrolein, glycidyl methacrylate, epoxy polymers, gum arabic, polyviyl alcohol, methyl cellulose, carboxymethyl cellulose, hydroxyethyl cellulose, arabinogalactan, polyacrylic acid, ethyl cellulose, polyethylene polymethacrylate, polyamide (nylon), polyethylene vinyl acetate, cellulose nitrate, silicones, poly(lactide-co-glycolide), paraffin, carnauba, spermaceti, beeswax, stearic acid, stearyl alcohols, glyceryl stearate, shellac, cellulose acetate phthalate, zein, hydrogels or the like.

Possible functional groups include alkanes, cycloalkanes, alkenes, alkynes, phenyl substituents, benzyl substituents, vinyl, allyl, carbenes, alkyl halides, phenol, ethers, epoxides, ethers, peroxides, ozonides, aldehydes, hydrates, imines, oximes, hydrazones, semicarbazones, hemiacetals, hemiketals, lactols, acetal/ketal, aminals, carboxylic acid, carboxylic acid esters, lactones, orthoesters, anhydrides, imides, carboxylic acid halides, carboxylic acid derivatives, amides, lactams, peroxyacids, nitriles, carbamates, ureas, guanidines, carbodiimides, amines, aniline, hydroxylamines, hydrazines, hydrazones, azo compounds, nitro compounds, thiols, mercaptans, sulfides, phosphines, P-Ylene, P-Ylides, biotin, streptavidin, metallocenes, or the like.

Possible release mechanisms include diffusion, dissolution, degradation control, erosion, or similar.

It is conceivable that a combined release mechanism is present.

Possible linkers include biopolymers, proteins, silk, polysaccarides, cellulose, starch, chitin, nucleic acid, synthetic polymers, homopolymers, polyethylenes, polypropylenes, polyvinyl chloride, polylactam, Natural rubber, polyisoprene, copolymers, random copolymers, gradient copolymer, alternating copolymer, block copolymer, graft copolymers, arcylnitrile butadiene styrene (ABS), styrene acrylonitrile (SAN), buthyl rubber, polymer blends, polymer alloy, inorganic polymers, polysiloxanes, polyphophazenes, polysilazanes, ceramics, basalt, isotactic polymers, syndiodactic polymers, atactic polymers, linear polymers, crosslinked polymers, elastomers, thermoplastic elastomers, thermosets, semi-crystalline linkers, thermoplastics, cis-trans polymers, conductive polymers, supramolecular polymers.

A linker can be any form of connection between a capsule and a functional group.

Further, the present invention relates to a method for preparing a multi-component system. According thereto, it is provided that in a method for preparing a multi-component system comprising at least one first substance and comprising at least one second substance, wherein the first substance and the second substance are present in a plurality of portions of substance, wherein the multi-component system can be activated, the method comprises the following steps:
the first portions of substance are formed with at least a first functional group and provided with a first linker,
the second portions of substance are formed with at least one second functional group and provided with a second linker,
the first functional group reacts via a predefined interaction with the second functional group so as to bind them together, and
the distance of the functional groups to the respective portion of substance is tuned by the respective linker.

It can be provided in particular that the first portions of substance are formed with at least one third functional group and are provided with a third linker, the third functional group having in each case at least one protective group, so that only correspondingly functionalized portions of substance of the first substance can bind to the portions of substance of the first substance, and the method further comprising at least the step that the protective groups are initially present and are only removed when the first portions of substance are to be linked to one another by means of the third functional groups. This prevents the portions of substance, in particular capsules, of the first substance from already and preferably combining with further portions of substance of the first substance. The protective groups may be removed after introduction into gas, low viscosity, liquid, high viscosity or solid phase, whereby the intra-crosslinking takes place.

The multi-component system may be a multi-component system as described above.

Possible fields of application of the process or system according to the invention include biotechnology, cosmetics, the pharmaceutical industry, the food industry, the chemical industry, agriculture, packaging technology, waste recycling, the textile industry, the manufacture of fiber composites, electrical engineering, mechanical engineering, medical technology, microtechnology, the automotive industry, paints, varnishes or the like.

Explicitly disclosed is thus the use of the process and/or system described above and also below for one of the following applications, alone or in combination, namely biotechnology, the pharmaceutical industry, cosmetics, the food industry, the chemical industry, agriculture, packaging technology, waste recycling, the textile industry, the manufacture of fiber composites, electrical engineering (e.g. in connection with the connection of electronic components, chip technology or the like), mechanical engineering, medical technology, microtechnology, the automotive industry or the like. In particular, the following would be worth mentioning in the cosmetics field:

In cosmetics there are many two-phase or multi-phase products. Often, there is an aqueous and an oily component. The 2C-microcapsule technology makes it possible to bring both phases into solution in a defined ratio.

In another embodiment, the two-phase products with the 2C capsules can be applied in a defined ratio onto a cotton pad. On the one hand, this would have the advantage that the substances do not dry out and can therefore be stored in normal packaging. On the other hand, the efficiency with which the substances develop their effect is significantly increased with the same material input. The efficiency increase of two substances can also be applied to creams, masks, etc.

In general, the principle of two-phase systems as described above can be applied to all multiphase systems.

In addition, the principle can generally be used to increase the yield of reactions and/or to make reactions more effective.

In the area of product development, self-healing products would be conceivable, for example:

The 2C-system can also be used for self-healing products. In one variant, the monomer is in one capsule and the activator or the second monomer is in the other capsule. Through targeted activation, the capsule complex reacts with the surrounding medium and binds the fragments together.

For example, the capsules could be placed in paper. In one capsule would be sugar monomers, in the other capsule would be the corresponding enzyme. Activation, e.g. by UV radiation, would cause the capsules to burst, the enzyme would bind the corresponding sugar monomers to the fibers and the breakage would thus be repaired.

The same principle could be applied to fibers, especially plastic fibers. The monomers would be present in one capsule, the initiator for polymerization in the other phase.

This principle can also be applied to paints, varnishes and many other materials. Further details and advantages of the invention will now be explained with reference to an embodiment shown in more detail in the drawings.

The following is shown:

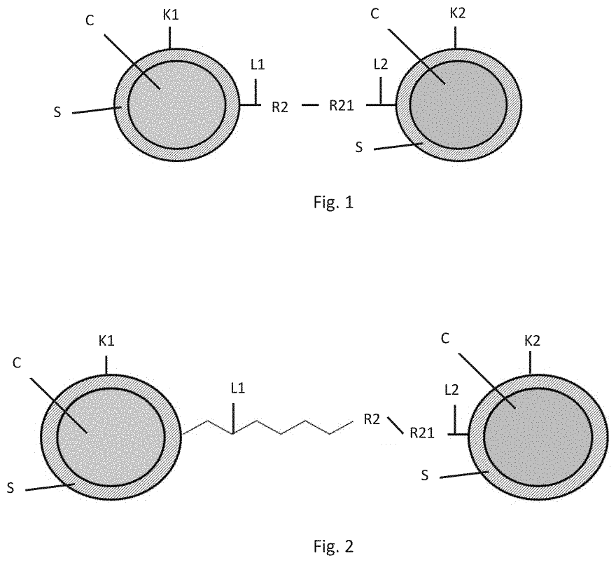

FIG. 1 an embodiment of a multi-component system according to the invention with a first substance and a second substance;

FIG. 2 a further embodiment of a multi-component system according to the invention with a first substance and a second substance;

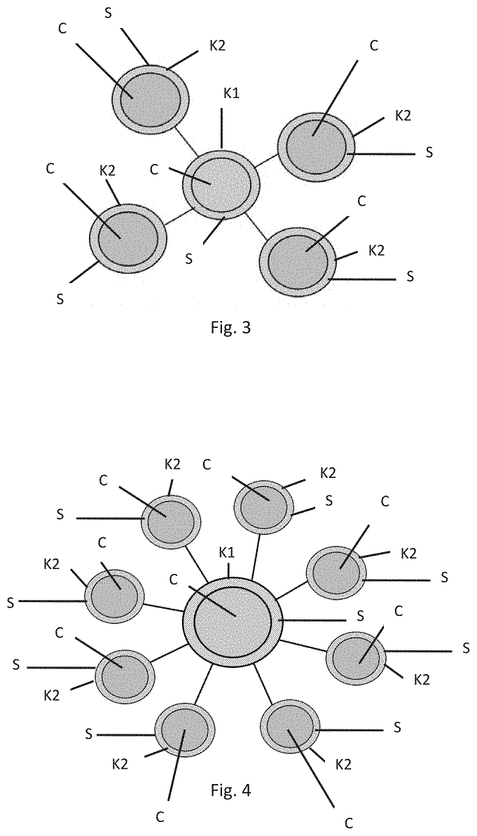

FIG. 3 a further embodiment of a multi-component system according to the invention as shown in FIG. 1 or FIG. 2;

FIG. 4 a further embodiment of a multi-component system according to the invention as shown in FIG. 1, FIG. 2 or FIG. 3;

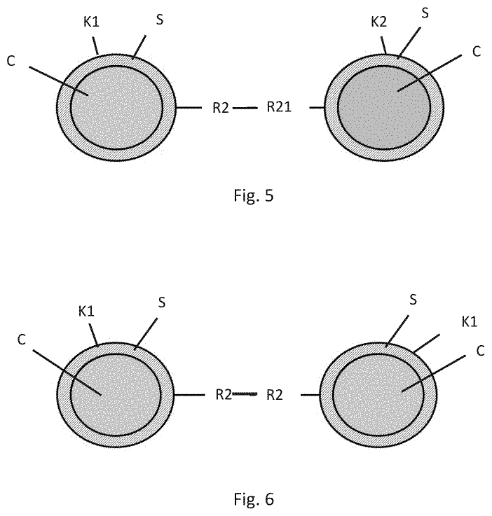

FIG. 5 an embodiment of an inter-crosslinking of two different portions of substance/capsule population according to the invention;

FIG. 6 an example of an intra-crosslinking of two identical portions of substance/capsule population according to the invention;

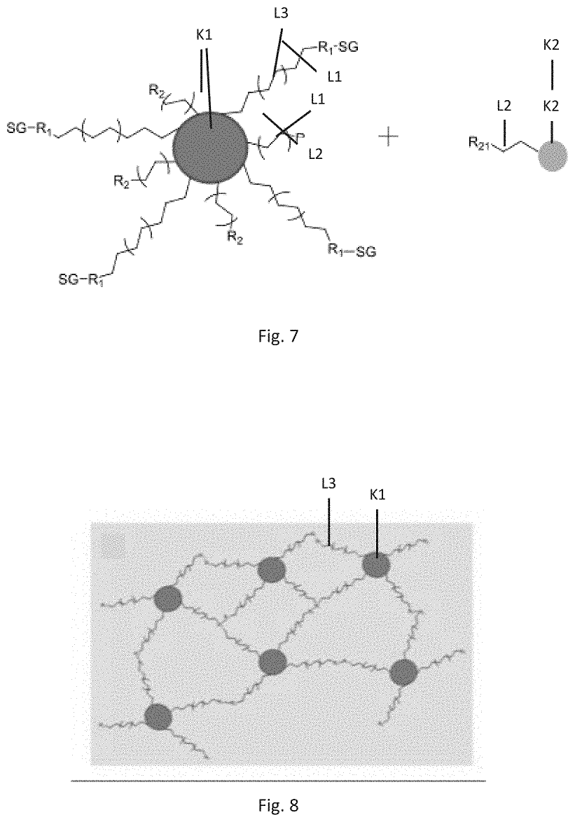

FIG. 7 an embodiment of a two-component system according to the invention;

FIG. 8 an embodiment of an intra-crosslinked capsule system according to the invention:

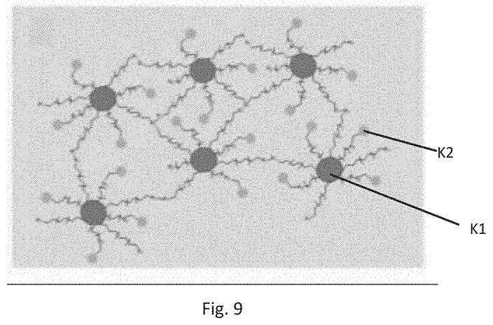

FIG. 9 an embodiment of an inter- and intra-crosslinked two-component system according to the invention as shown in FIG. 7;

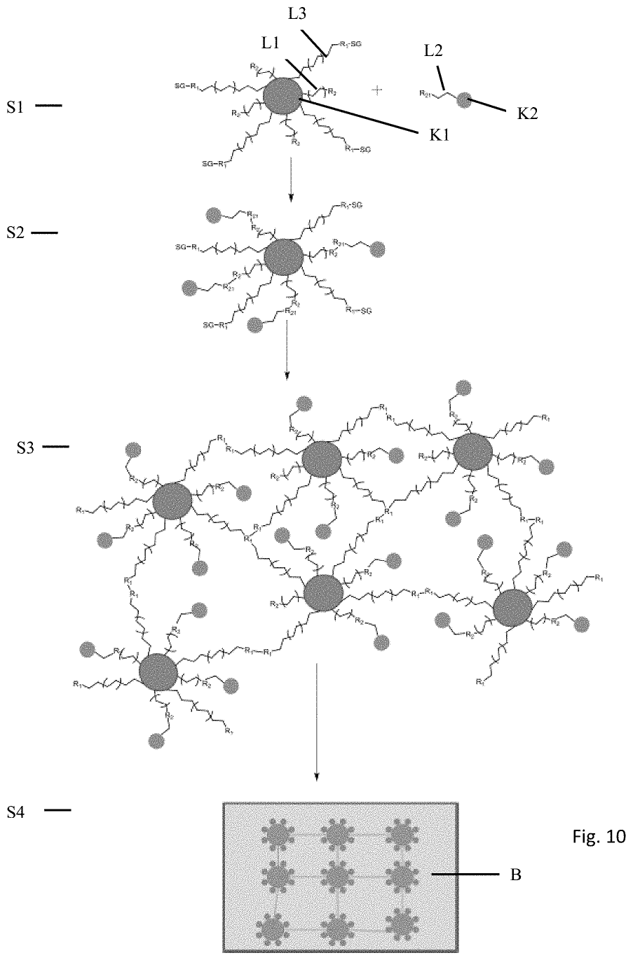

FIG. 10 a flowchart of the workflow of manufacturing a two-component adhesive tape according to the present invention;

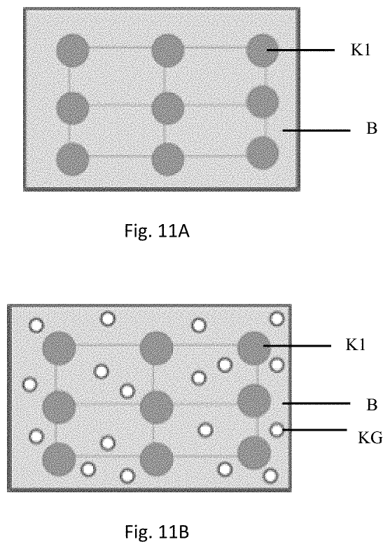

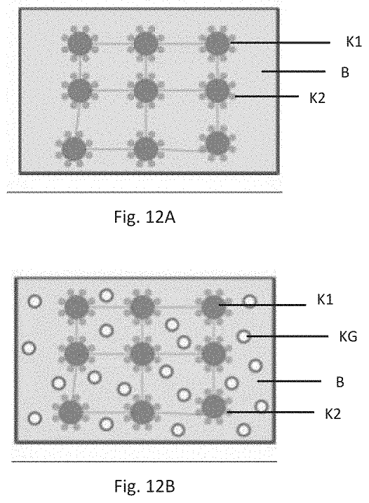

FIG. 11A an embodiment of intra-crosslinked capsules of a one-component system according to the present invention;

FIG. 11B an embodiment of intra-crosslinked capsules of a one-component system and non-crosslinked gas-filled capsules according to the present invention;

FIG. 12A an embodiment of inter- and intra-crosslinked capsules of a two-component system according to the present invention;

FIG. 12B a schematic representation of inter- and intra-crosslinked capsules of a multi-component system and non-crosslinked gas-filled capsules according to the present invention;

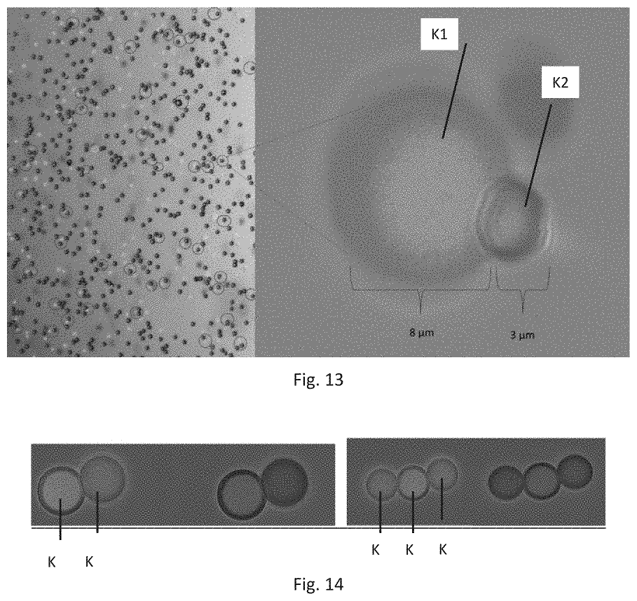

FIG. 13 an illustration of microcapsule binding ratios in a two-component system according to the present invention; and

FIG. 14 an illustration of the binding of microcapsules according to the invention with the same size but with a different functionalization.

FIG. 1 shows an embodiment of a multi-component system according to the invention with a first substance and a second substance.

According to this embodiment, the multi-component system can be activated.

It is possible that the first substance and the second substance are present in multiple portions of substance.

According to this embodiment, the first substance is present in a capsule population K1.

In other words, According to this embodiment, the first portions of substance are first capsules K1.

According to this embodiment, the second substance is present in a capsule population K2.

In other words, According to this embodiment, the second portions of substance are second capsules K2.

Generally, it is possible that a portion of substance of the first substance and/or the second substance is arranged in a capsule K, in particular a nanocapsule and/or microcapsule.

Thereby, the portion of substance forms a core C (also called core) in K1 and K2, respectively, which is surrounded by a capsule shell S (also called shell). This is therefore a “core-shell” construct. In principle, however, core-shell-shell constructs are also conceivable.

According to this embodiment, the first portions of substance are formed with at least one first functional group R2 and are provided with a first linker L1.

According to this embodiment, the second portions of substance are formed with at least one second functional group R21 and provided with a second linker L2.

According to this embodiment, the first functional group R2 reacts with the second functional group R21 via a predefined interaction and binds them together.

According to this embodiment, the distance of the functional groups to the respective portion of the substance is tuned by the respective linker L.

The capsules shown in FIGS. 2-6 are identical in construction to the capsules K1 and K2 shown in FIG. 1.

According to this embodiment, the first portions of substance are formed with at least one first functional group R2 and are provided with a first linker L1.

According to this embodiment, the second portions of substance are formed with at least one second functional group R21 and provided with a second linker L2.

According to this embodiment, the first functional group R2 reacts with and the second functional group R21 via a predefined interaction and binds them together.

According to this embodiment, the distance of the functional groups to the respective portion of the substance is tuned by the respective linker L.

It is possible that the first linker L1 is longer than the second linker L2, cf. FIG. 2.

Alternatively, it is possible that the second linker L2 is longer than the first linker L1.

Alternatively, it is possible that both linkers L1 and L2 are of equal length.

FIG. 3 shows an embodiment of a multi-component system according to the invention as shown in FIG. 1 or FIG. 2.

According to this embodiment, the first portions of substance and the second portions of substance are different.

In other words, According to this embodiment, the capsules K1 of the first capsule population are different from the capsules K2 of the second capsule population.

According to this embodiment, the first portions of substance are connected or connectable to a larger number of portions of substance than the second portions of substance.

In other words, According to this embodiment, the capsules K1 are connected or connectable to a greater number of capsules K than the capsules K2.

Alternatively, it is possible that the second portions of substance are connected or connectable to a greater number of portions of substance than the first portions of substance.

In other words, it is possible that the capsules K2 are connected or connectable to a greater number of capsules K than the capsules K1.

FIG. 4 shows a further embodiment of a multi-component system according to the invention as shown in FIG. 1, FIG. 2, or FIG. 3.

According to this embodiment, the first portions of substance and the second portions of substance have substantially different sizes.

According to this embodiment, the first capsules K1 have a substantially larger size than the second capsules K2.

Generally, a capsule K1 of a first substance may have a different size than a capsule K2 of a second substance, in particular wherein the capsule K1 of the first substance is larger than the capsule K2 of the second substance.

Alternatively, it is possible for the second portions of substance to have a substantially larger size than the first portions of substance.

Alternatively, it is possible for the first portions of substance and the second portions of substance to have a substantially identical size.

It is not shown that the first portions of substance may have a substantially identical size and/or that the second portions of substance may have a substantially identical size.

FIG. 5 shows an embodiment of an inter-crosslinking of two different portions of substance according to the invention.

According to this embodiment, a capsule K1 and a capsule K2 are inter-crosslinked.

According to this embodiment, a capsule K1 and a capsule K2 are inter-crosslinked via functional groups R2 and R21.

FIG. 6 shows an embodiment of an intra-crosslinking of two equal portions of substance according to the invention.

According to this embodiment, two capsules K1 are intra-crosslinked.

According to this embodiment, the two capsules K1 are intra-crosslinked via the functional groups R2-R2.

FIG. 7 shows an embodiment of a two-component system according to the invention.

According to this embodiment, the two-component system is a two-component microcapsule system.

According to this embodiment, the two-component system is a two-component microcapsule system that has not yet reacted with each other via a predefined interaction.

In particular, two different capsule populations K1 and K2 are shown, wherein a first substance is contained in the first capsule K1 and a second substance is contained in the second capsule K2.

The capsules K1 and K2 shown are exemplary of a plurality of capsules K1 and K2, e.g. to be referred to as capsule populations.

According to this embodiment, the first substance contained in the one capsule K1 is a first adhesive component.

According to this embodiment, the second substance contained in the second capsule K2 is a second adhesive component.

In other words, the first substance and the second substance are components of a multi-component adhesive, in particular a two-component adhesive.

It is generally possible that the two different capsule populations K1 and K2 were produced in separate batch reactors.

The K1 and K2 capsules of the two capsule populations are functionalized.

The first capsules K1 were formed with two different linkers L1 and L3 of different length and with different functional groups R1 and R2 on the surface (surface functionalization).

In other words, the functional groups R are heterogeneously formed.

In an alternative embodiment, it is possible that the functional groups R are homogeneously formed.

The second capsules K2 were formed with the linker L2 and with the functional group R21.

The functional group R21 of the second capsule K2 reacts covalently with the functional group R2 of the first capsule K1.

According to this embodiment, it is possible that the first capsules K1 are connected or connectable to a greater number of capsules K than the second capsules K2.

In an alternative embodiment, it is possible that the second capsules K2 are connected or connectable to a greater number of capsules K than the first capsules K1.

The linker L3 and the functional group R1 should crosslink the first capsules K1 with each other (intra-crosslinking).

Via the linker L1 and the functional group R2 and the linker L2 and the functional group R21, the capsules K2 are covalently bound to the first capsule K1 (inter-crosslinking).

By activating both capsules K1 and K2, the contents of the capsules K1 and K2 can be released, resulting in a mixing of both components.

Generally, it is possible to tuned the number of second capsules K2 which bind to the first capsules K1 by adjusting the density of the surface functionalization or the number of functional groups R2 of the first capsule K1.

In general, two reactive substances can be separately encapsulated in the capsules K1 and K2 and bound in a specific ratio via, inter alia, covalently (e.g. click chemistry), by weak interaction, biochemically (e.g. biotin-streptavidin) or by other means.

It is generally possible for more than two different capsules Kn to encapsulate more than two different substances, e.g. reactive substances.

It is generally possible that the different capsules Kn are formed with more than two linkers Ln and with different functional groups Rn.

It is generally possible for a linker L to be any form of link between a capsule and a functional group.

It is generally possible that, in the case of heterogeneous functionalization, a functional group R can be used for binding to surfaces, fibers or textiles.

As with existing capsule systems, any conceivable substance can be introduced into the capsules K1 and/or K2 and/or Kn.

Activation of the two-component system may be accomplished by at least one of a change in pressure, pH, UV radiation, osmosis, temperature, light intensity, humidity, or the like.

In general, a two-component capsule system could be implemented in any medium.

FIG. 8 shows an embodiment of an intra-crosslinked capsule system according to the invention.

According to this embodiment, the intra-crosslinked capsule system according to the invention is an intra-crosslinked microcapsule system.

A single component system is shown.

A capsule population K1 is shown.

The capsules K1 are filled with a substance.

According to this embodiment, the capsules K1 are filled with an adhesive.

According to this embodiment, the capsules K1 are filled with a one-component adhesive.

Alternatively, the capsules K1 may be filled with any conceivable gaseous, solid, viscous and/or liquid substance.

Alternatively, the capsules K1 may be filled with living organisms and/or viruses.

The capsules K1 were functionalized.

The capsules K1 were provided with linkers L3.

It is not shown that capsules K1 are formed with functional groups R1 (on linker L3).

The linkers L3 crosslink the capsules K1 with each other (intra-crosslinking).

The distance between the capsules K1 can be tuned by the length of the linker L3.

The degree of intra-crosslinking of the capsules K1 can be tuned depending on the density of the surface functionalization R1.

The length of the linker L3 has to be chosen in such a way that the radius of the content of the released liquid of the capsules K1 slightly overlaps with the content of the adjacent capsules K1 in order to ensure cross-linking.

For a higher viscosity environmental medium (such as an adhesive tape), the length of the linker L3 would be smaller than for a lower viscosity medium such as a paste or liquid.

FIG. 9 shows an embodiment of an inter- and intra-crosslinked two-component system according to the invention as shown in FIG. 7.

The first capsules K1 and the second capsules K2 are filled with different substances.

According to this embodiment, the capsules K1 have a substantially identical size.

According to this embodiment, the capsules K2 have a substantially identical size.

According to this embodiment, the capsules K1 and the capsules K2 have a different size.

In an alternative embodiment, it is possible that the capsules K1 and the capsules K2 have a substantially identical size.

The basic system corresponds to the illustration in FIG. 8.

Moreover, the first capsules K1 are heterogeneously formed with a linker L1.

A second capsule population K2 binds to the linker L1, cf. FIG. 1.

In other words, the two-component system has a network structure with interstices, wherein the network structure is formed by the first capsules K1, and wherein at least one capsule K2 is arranged in each of the interstices, at least in sections.

It is generally possible that the two-component capsules K1 and K2 with different contents, are introduced into the gas phase. For example, they could be used in inhalers or other drug delivery systems. The inactivated capsules reach the site of action where they are activated and the contents are released. Surfaces could also be coated with this dispersion.

It is generally possible for the two-component capsules K1 and K2 with different contents to be introduced into a paste-like medium. For example, a two-component adhesive could be used for this purpose. The paste is inert and can be processed well until the capsules are activated and react with each other. As described above, the ideal mixing ratio of the adhesives is tuned by the ratio of the first and second capsules K1 and K2.

The advantage of the ideal composition of the two-component capsule systems can also be used in liquid systems. Since both capsules K1 and K2 of the two-component capsule system are in close proximity, it is very likely that the capsules K1 and K2 react faster and more defined with each other than individually in dispersion.

FIG. 10 shows a flow diagram of the workflow of manufacturing a two-component adhesive tape according to the invention.

FIG. 10 is substantially based on a two-component capsule system as shown in FIG. 7.

Overall, the production of a two-component adhesive tape according to the invention is divided into four steps S1-S4.

In a first step S1, the first capsules K1 and the second capsules K2 are functionalized, cf. FIG. 7.

In the present two-component system, the first capsules K1 are heterogeneously formed with two linkers L1 and L3 having functional groups R1 and R2.

In a separate batch reaction, the second population of capsules K2 is functionalized with linker L2 containing the functional group R21.

The functional group R21 is to be chosen such that it reacts (covalently) with the functional group R2 of the first capsule K1 in the later reaction step.

In a second step S2, the functionalized second capsules K2 are added to the functionalized first capsules K1.

The functional groups R2 and R21 bind (covalently) to each other (inter-crosslinking).

It is generally possible that a third or any number of further capsule populations K3-Kn are also added to a first capsule population K1 and/or a second capsule population K2.

Each additional capsule population K3-Kn may in turn be functionalized with at least one functional group.

In a third step S3, the heterogeneous capsule dispersion from the preceding step S2 is introduced into the adhesive, in this case an adhesive tape B, which is still low in viscosity.

A predetermined (intra)-crosslinking reaction occurs, which is formed throughout the entire area of the adhesive tape B.

In a fourth step S4, the cross-linked two-component capsule populations are applied and the adhesive tape B is dried.

In this case, the viscosity of the adhesive tape B increases significantly, but the network remains homogeneously distributed on the adhesive tape.

It is shown that in step S1, in order to prevent the first capsules K1 from cross-linking with each other prematurely during functionalization, a protective group SG may still be formed on the functional group R1 of the linker L3.

It is further shown that in step S3, the protective groups SG are removed.

It is not shown that removal of the protecting group allows intra-crosslinking of the capsules K1.

Possible applications are in different ambient media:

Based on the workflow described herein for producing a two-component adhesive tape according to the invention, the two-component encapsulation system can alternatively be applied in other media and with any encapsulated substances.

Conceivable environmental media include gas, liquid, pasty, low and high viscosity media as well as solid surface coatings.

It is generally possible for the capsules K to be nanocapsule or microcapsules.

Generally, the method enables the preparation of further multi-component systems having at least one first substance and having at least one second substance, wherein the first substance and the second substance are present in multiple portions of substance, wherein the multi-component system can be activated, comprising the following steps:
the first portions of substance are formed with at least one first functional group R2 and provided with a first linker L1,
the second portions of substance are formed with at least one second functional group R21 and provided with a second linker L2,
the first functional group R2 reacts via a predefined interaction with the second functional group R21 so that they are linked to each other, and
the distance of the functional groups R to the respective portion of substance is tuned by the respective linker L.

It is generally possible that the first portions of substance are formed with at least one third functional group R1 and provided with a third linker L3.

It is generally possible that the third functional group R1 comprises at least one protective group SG in each case, so that only correspondingly functionalized portions of the first substance can bind to the portions of the first substance.

It is generally possible that the method further comprises at least the step of initially having the protective groups SG and removing them only when the first portions of substance are to be bonded together by means of the third functional groups R1.

It is generally possible that the functional groups R1 each have at least one protecting group, so that only correspondingly functionalized portions of the second substance can bind to the portions of the first substance.

Further, it is generally possible for the method of making a multi-component system to further comprise at least the step of initially having the protecting groups and removing them only when the first and second portions of substance are to be combined by means of the first and second functional groups R2, R21.

FIG. 11A shows a schematic diagram of intra-crosslinked capsules of a single component system in a high viscosity system according to the present invention.

According to this embodiment, the crosslinked single component system is incorporated into a high viscosity system as described in FIG. 8.

The high viscosity system is an adhesive tape B.

Alternatively, other high-viscosity, liquid, gaseous, paste-like or low-viscosity systems are conceivable.

According to this embodiment, the adhesive tape B is a single-sided adhesive tape B.

Alternatively, double-sided versions of an adhesive tape B are also possible.

Usually, there is a diffusion problem with highly viscous systems, so that the contents of the capsules K1 in the adhesive tape B do not achieve cross-linking between the two materials to be bonded.

Due to the (intra)-crosslinking of the one-component system, the spacing and the degree of crosslinking of the capsules K1 can be tuned such that the contents of the capsules K1 form a crosslinking system through the highly viscous adhesive.

This basic principle can also be extended to a two-component system as shown in FIG. 12A. Therein, the (inter- and intra-) cross-linking mechanism is used.

It is not shown that the two-component system can also be introduced into the adhesive tape only with prior inter-crosslinking of the capsules K1 and the capsules K2.

FIG. 11B shows a schematic representation of intra-crosslinked capsules of a one-component system and non-crosslinked gas-filled capsules according to the present invention.

Alternatively, the non-crosslinked capsules may be filled with solid or liquid materials.

In addition to the intra-crosslinked capsules K1 of the one-component system according to FIG. 11A, a further population of non-crosslinked gas-filled capsules KG can be introduced into the highly viscous adhesive, such as an adhesive tape B, which release the gas when bursting and thus either create free space for the liquid component of the capsules K1 or enable the adhesive tape to be removed again.

It would also be conceivable to include a dissolvable placeholder (e.g., fibers or the like) in the adhesive tape B.

This would create channels in which the liquid adhesive of the capsules K1 can spread and cross-link over a large area within the adhesive tape B.

Another possibility would be to fill the liquid-filled capsules K1 into tubes and place them in the adhesive tape B.

Thus, cross-linking could occur to the extent of the tube length.

This basic principle can also be extended to a two-component system as shown in FIG. 12B.

Here, the mechanism of inter- and intra-crosslinking is used.

In addition to the first capsules K1 of the single component system, a second capsule population K2 is introduced.

This mechanism allows a two-component adhesive system to be introduced in a tape B.

The systems described are not limited to one-component capsule systems or two-component capsule systems.

Depending on the size and functionalization of the respective system, any number of capsule populations Kn can be bound and inter-crosslinked.

By combining the individual components, a very wide range of new functionalities and thus new possibilities of application can be developed.

In the following, the production of polymethyl methacrylate microcapsules is described as an example:

First, 2.5 g polymethyl methacrylate (PMMA) is dissolved in 11.5 mL toluene. Then, oil is added under stirring. For microencapsulation, the homogeneous solution is added to 45 mL of a 1 wt.-% polyvenyl alcohol (PVA) solution. The emulsion is stirred at 800 rpm for 30 min. The toluene is then evaporated. The resulting microcapsules K with a PMMA coating material are washed with distilled water and centrifuged at 5,000 rpm and dried overnight at 50° C. in a vacuum oven.

Then the surface of the microcapsules is silanized. The microcapsules are placed in a fluidized bed reactor. A 5% aqueous (3-aminopropyl)triethoxysilane (APTES) solution is used as the coating material. After the coating process, the microcapsules are dried for 1 h at 80° C. in a vacuum oven to obtain optimal binding of the aminosilane to the surface. In addition, the surface of the microcapsules K can be activated with oxygen plasma before the reaction.

For the inter-crosslinking of two capsule populations K1 and K2 (capsules K with different contents), the complementary capsule population K can be functionalized with carboxyl groups. Here, the procedure is analogous to the silanization described above. However, instead of (3-aminopropyl)triethoxysilane (APTES), a silane-PEG-COOH is used.

Subsequently, the capsules K can still be sieved with a sieve having different pore sizes in order to increase the monodispersity. This has the advantage that in the subsequent binding process, the volume ratios of the two capsule contents can be precisely tuned via the size of the capsules K.

Then the microcapsule binding takes place. The first microcapsule K1 is functionalized with primary amines, while the second microcapsule K2 is functionalized with carboxyl groups. In the next step, 80 μL of a 10% carboxyl functionalized microcapsule suspension is added to an aqueous solution and 7 μL of a 2M (1-ethyl-3-(3-dimethylaminopropyl)carbodiimide) solution (EDC solution) and 7 μL of a 0.3 M N-hydroxysuccinimide) solution (NHS solution) are added and stirred for one hour at room temperature. The carboxyl function is converted to the active ester. Amine microcapsules K1 are then added to the solution in the same ratio as the carboxyl microcapsules K2 and allowed to bind together for two hours at room temperature with gentle stirring. The capsules are then filtered through a sieve, washed with distilled water and dried in a vacuum oven at 50° C. for one hour.

In FIG. 13, it can be seen that most of the microcapsules K bind together in a 1:1 ratio.

In addition, there are a few microcapsules K that bind in a 1:2 ratio or have not been bound at all.

In order to ensure the quality of the two-component microcapsules K, the microcapsules K are then purified via a sieve with different pore sizes according to size or according to their binding ratio. The binding ratio of the microcapsules K can also be influenced by the number of functional groups on the microcapsules K.

It is possible that microcapsules K with the same size (e.g. 8 μm) but with a different functionalization were bound together. In the case of functionalization with linear polymers, the 1:1 binding predominates, cf. FIG. 14. In the case of functionalization with polymers that exhibit multivalence, the triple binding predominates.

It is also possible that the functionalization of microcapsules occurs via adsorption.

In particular, microcapsules having plastic surfaces may be functionalized via adsorption. Preferred examples of plastic surfaces are acrylic resin, polylactic acid, nylon 6 and 12, epoxy resins, and polystyrene.

For adsorption to the surface of the microcapsules, alkyl chains or primary amines are preferably used.

The second functional group can be chosen freely and is thus available for the binding of the microcapsules in the next step.

The plastic surface of the microcapsules can be formed directly in the microencapsulation process or in a second step for a multilayer microcapsule obtained in this way.

In an alternative embodiment, the second microcapsule population may be made and/or coated with metal particles or a metal shell.

The two microcapsule populations with 4-aminobenzenethiol as binder of both microcapsule populations are added.

The primary amine binds to the microcapsules via adsorption with the plastic surface, the thiol group binds to the metal surface.

Furthermore, functionalization is possible during the micro capsulation process as described in WO2017192407.

Accordingly, for example, a mixture comprising water (20 mL), ethyl acetate (5 mL), sodium bicarbonate (0.580 g), about 1.0 mg of Sudan Black and a drop of Tween 20 is vigorously mixed (5 minutes at 500 rpm) at room temperature using a mechanical stirrer (about 500 mL). 77 mg of 1,3-bischlorosulfonylbenzene are added to the mixture, after which stirring is continued for about 3 minutes. The mixture is then treated with 3,5-diaminobenzoic acid and stirred vigorously for a further 72 hours. In order to observe the reaction taking place in the mixture, aliquots are taken thirty minutes after vigorous stirring has commenced, and every 12 hour thereafter. On microscopic observation, the aliquots show a formation of capsules of 1 to 2 micrometers in diameter, with the dye Sudan black contained therein. The reaction is completed after a few hours. It is postulated that the capsules have multiple —COOH groups on the surface.

Furthermore, functionalization during the micro capsulation process is possible according to the further methods described in WO2017192407.

Accordingly, a second portion of material can be prepared in a separate batch approach using the same method, only with primary amines on the surface.

Subsequently, the microcapsule population can be activated with COOH on the surface as in the example before with EDC/NHS, the amine capsule population is added and the capsules bind covalently to each other. In the next step, the capsules can be washed, (filtered if necessary) and dried. The capsules thus contained can then be incorporated into another environmental medium.

For example, another conceivable method of manufacture is described in Yip, J and Luk, MYA, Antimicrobial Textiles, Woodhead Publishing Series in Textiles, 2016, Pages 19-46, 3-Microencapsultion technologies for antimicrobial textiles.

It is conceivable that the microcapsules with metal particles can also be applied via charge.

Intra-crosslinking is possible.

It is conceivable that after the production of the microcapsules with metal particles on the surface, a mixture of alcohol and mercaptans (SAM polymer) is added to the capsules.

In the case of functionalized thiols, the second functional group can be chosen arbitrarily. The thiol bonds bind to the metal surface. The remainder, i.e. the second functional group of the thiol molecule, is available as a functional group for the microcapsule crosslinking.

By selecting one or more SAM polymers to be added to the microcapsules, the functional groups of the surface can be made homogeneous or heterogeneous.

In addition, the length of the linker can be tuned with a suitable mercaptan.

In one embodiment, it is possible to select ethanethiol for a short linker. For a longer linker, an 11-mercaptoundecannoic may be selected.

Furthermore, it is possible to bind the thus functionalized surface of the microcapsules with a second polymer, e.g. with a PEG, in order to further increase the length of the linker.

Disulfites, phosphoric acids, silanes, thiols, and polyelectrolytes may be used as SAM surfaces. In particular, acetylcysteine, dimercaptosuccinic acid, dimercaptopropanesulfonic acid, ethanethiol (ethyl mercaptan), dithiothreitol (DTT), dithioerythritol (DTE), captopril, coenzyme, A, cysteine, penicillamine, 1-propanethiol, 2-propanethiol, glutathione, homocysteine, mesna, methanethiol (methyl mercaptan) and/or thiophenol may be used.

Inter-crosslinking is possible.

The microcapsules containing the metal nanoparticles can be prepared as described above.

Then, a mixture of alcohol and dithioether can be added.

The one functional group R is protected.

This is how the microcapsules are functionalized.

The number of metal nanoparticles on the surface of the microcapsules can then be used to tune the number or density of the functionalization and thus the number of functional groups. This makes it possible to determine the number of microcapsules K2 that react with each other via intra- or inter-crosslinking.

In the next step, the microcapsules can be inserted into the desired environmental medium, such as a pressure-sensitive adhesive (or the like).

For inter-crosslinking, the use of 4-isocyanate butane-1-thiol is conceivable, whereby the NCO groups are protected.

The removal of the protective groups and thus the activation of the functional groups R takes place in the still low viscosity pressure sensitive adhesive. The NCO groups released in this way can crosslink with each other in an aqueous environment (e.g. the solvent of the pressure-sensitive adhesive) to form urea.

### REFERENCE SIGN

B Adhesive tape
C Core
K Capsule/capsule population
K1 Capsule 1/Capsule population 1
K2 capsule 2/capsule population 2
K3 Capsule 3/Capsule population 2
Kn Capsule n/Capsule population n
KG Gas capsule
L Linker
L1 Linker 1
L2 Linker 2
R functional group
R1 functional group 1
R2 functional group 2
R21 functional group 21
S Capsule, Shell
S1 Step 1
S2 Step 2
S3 Step 3
S4 Step 4
SG protection group

1: A multi-component system comprising at least one first substance and at least one second substance, wherein the multi-component system can be activated, wherein the at least one first substance and the at least one second substance are present in a plurality of portions of substance,
wherein first portions of substance are formed with at least one first functional group and are provided with a first linker, and
wherein second portions of substance are formed with at least one second functional group and are provided with a second linker,
wherein the at least one first functional group reacts with and binds to the at least one second functional group via a predefined interaction, and
wherein a distance of the at least one first functional group and the at least one second functional group to the respective portion of substance is tuned by the respective linker (L).

2. The multi-component system according to claim 1, wherein the first linker is longer than the second linker or vice versa.

3. The multi-component system according to claim 1, wherein the first portions of substance are connected or connectable to a larger number of portions of substance than the second portions of substance, or vice versa.

4: The multi-component system according to claim 1, wherein the at least one first functional group and the at least one second functional group are homogeneously or heterogeneously formed.

5: The multi-component system according to claim 1, wherein the first portions of substance have a substantially identical size and/or that the second portions of substance have a substantially identical size.

6: The multi-component system according to claim 1, wherein the first portions of substance and the second portions of substance have a different size.

7: The multi-component system according to claim 1, wherein the multi-component system has a network structure with interstices,
wherein the network structure is formed by portions of the first substance, and at least one portion of the second substance is arranged in each of the interspaces, at least in sections of the network structure.

8. The multi-component system according to claim 1, wherein a portion of substance of the first substance and/or of the second substance is arranged in a capsule.

9: The multi-component system according to claim 8, wherein a capsule of the first substance has a different size than a capsule of the second substance.

10: The multi-component system according to claim 8, wherein capsules of the first substance have an identical size.

11: The multi-component system according to claim 1, wherein activation of the multi-component system is effected by at least one change of pressure, pH, UV radiation, osmosis, temperature, light intensity, and/or humidity.

12: The multi-component system according to claim 1, wherein the first substance and the second substance are components of a multi-component adhesive.

13: A method of preparing a multi-component system comprising at least one first substance and at least one second substance, the at least one first substance and the at least one second substance being present in a plurality of portions of substance, wherein the multi-component system can be activated, the method comprising:
forming first portions of substance, with at least one first functional group and provided with a first linker,
forming second portions of substance, with at least one second functional group and provided with a second linker,
reacting the at least one first functional group via a predefined interaction with the at least one second functional group so that they are bound together, and wherein a distance of the at least one first functional group and the at least one second functional group to the respective portion of substance is tuned by the respective linker.

14: The method according to claim 13, wherein the first portions of substance are formed with at least one third functional group and are provided with a third link,
wherein the at least one third functional group comprises at least one protective group in each case, so that only correspondingly functionalized portions of substance of the first substance can bind to portions of substance of the first substance, and
wherein the method further comprises at least removing the protective groups that are initially present, only when the first portions of substance are to be linked to each other by the at least one third functional group.

15. (canceled)

16: The multi-component system according to claim 8, wherein the portion of substance of the first substance and/or of the second substance is arranged in a nanocapsule and/or a microcapsule.

17: The multi-component system according to claim 9, wherein the capsule of the first substance is larger than the capsule of the second substance.

18: The multi-component system according to claim 12, wherein the first substance and the second substance are components of a two-component adhesive.
